(19) United States
(12) Patent Application Publication
(10) Pub. No.: US 2022/0082591 A1
(43) Pub. Date: Mar. 17, 2022

(54) HOUSING FOR ELECTRONIC POWER DEVICES FOR DRIVING AN ELECTRIC MOTOR OF AN ELECTRIC OR HYBRID VEHICLE

(71) Applicant: ELDOR CORPORATION S.P.A., Orsenigo (Como) (IT)

(72) Inventors: Fabio MARIGLIANO, Orsenigo (Como) (IT); Pasquale FORTE, Orsenigo (Como) (IT); Alessandro POLI, Orsenigo (Como) (IT)

(21) Appl. No.: 17/415,610

(22) PCT Filed: Dec. 18, 2019
(86) PCT No.: PCT/IB2019/060990

§ 371 Date: Jun. 17, 2021

(30) Foreign Application Priority Data
Dec. 20, 2018 (IT) 102018000020593

(51) Int. Cl. G01R 15/20; H05K 7/14

(52) U.S. Cl. CPC G01R 15/207; G01R 15/202; H05K 7/1427

(57) ABSTRACT

It is disclosed a housing for electronic power devices for driving an electric motor of an electric or hybrid vehicle. The housing comprises a perimeter element adapted to house a support for electronic power devices. The perimeter element comprises an electrical connector adapted to receive a direct voltage generated by a battery pack, comprises a metal conductor adapted to carry an alternating voltage for driving the electric motor, comprises a magnetic flux concentrator adapted to generate a magnetic field at least partially crossing the metal conductor. The concentrator surrounds the metal conductor and comprises an air opening adapted to house a Hall sensor to measure the current flowing across the metal conductor.

### BACKGROUND

### Technical Field

The present disclosure generally relates to the sector of electric or hybrid vehicles.

More particularly, the present disclosure concerns a housing for electronic power devices that drive the electric motor of an electric or hybrid vehicle.

### Prior Art

Modern electric or hybrid vehicles use three-phase asynchronous electric motors that are driven by means of three inverters, each of which performs a conversion of direct voltage (DC) into alternating voltage (AC), in order to suitably drive the three phases of the electric motor; the direct voltage is generated by a battery pack mounted in the electric or hybrid vehicle.

It is known that an inverter comprises several electronic power components to perform said conversion of the direct voltage into alternating voltage, such as for example power switches and transformers.

It is therefore necessary to provide suitable housings able to contain the printed circuit boards on which the electronic power components of the inverter are mounted and which are provided with suitable connectors for connection to the windings of the electric motor.

It is also known to carry out the monitoring of the current flowing in the windings of the electric motor, by means of the use of suitable current sensors.

The Applicant has observed that the known current sensors of an electric motor are not sufficiently precise and reliable.

Furthermore, the Applicant has observed that the housings for electronic power devices according to the prior art require an assembly of components which is too complex.

### BRIEF SUMMARY

The present disclosure relates to a housing for electronic power devices for driving an electric motor of an electric or hybrid vehicle as defined in the enclosed claim 1 and the preferred embodiments thereof described in dependent claims 2 to 10.

The Applicant has perceived that the housing for electronic control devices according to the present disclosure has the following advantages:
it allows to perform more accurate and more reliable measurements of the current flowing in the windings of the electric motor;
it simplifies the assembly of the housing;
it makes the seal of the metal elements in the housing more reliable during its use.

It is also an object of the present disclosure an electric power supply system of an electric or hybrid vehicle as defined in the enclosed claim 11 and the preferred embodiments thereof described in the dependent claims 12 and 13.

### BRIEF DESCRIPTION OF THE SEVERAL VIEWS OF THE DRAWINGS

Additional features and advantages of the disclosure will become more apparent from the description which follows of a preferred embodiment and the variants thereof, provided by way of example with reference to the appended drawings, in which:

FIGS. 1 and 2 show two perspective views of a housing for electronic power devices for driving an electric motor of an electric or hybrid vehicle according to the disclosure;

FIGS. 3 and 4 show two perspective, transparent views of said housing for electronic power devices according to the disclosure.

### DETAILED DESCRIPTION

It should be observed that in the following description, identical or analogous blocks, components or modules are indicated in the figures with the same numerical references, even where they are illustrated in different embodiments of the disclosure.

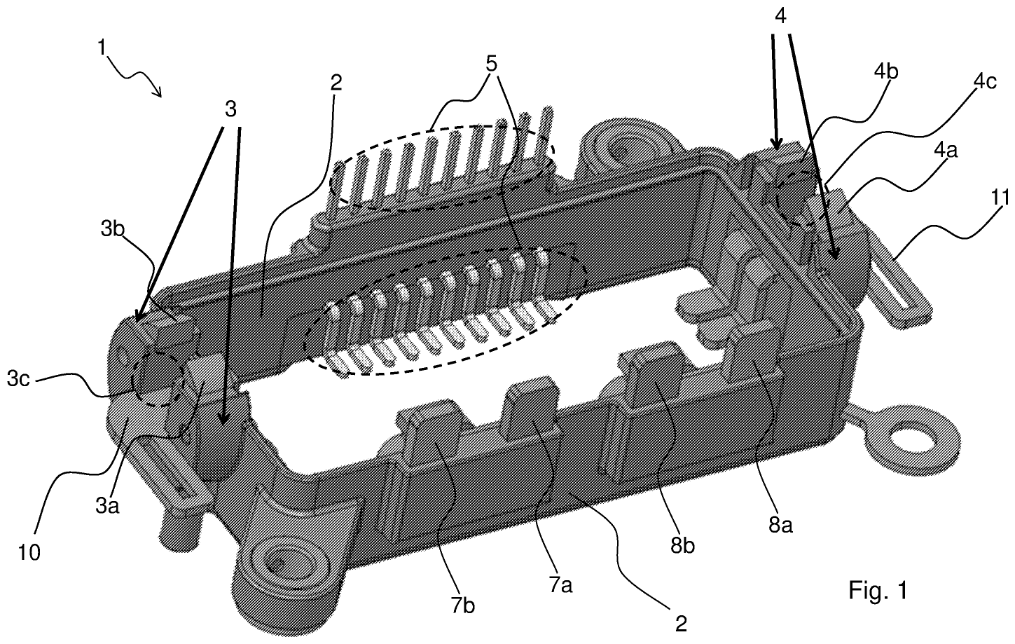

With reference to FIGS. 1, 2, 3 and 4, they show four perspective views of a housing 1 for electronic power devices that drive the electric motor of an electric or hybrid vehicle.

The vehicle is for example a motor vehicle with four wheels.

The housing 1 comprises a perimeter element 2 adapted to house a support (for example flat) for a plurality of electronic power devices, such as for example high-power switches (IGBT), transformers and capacitors.

In other words, the perimeter element 2 is a casing inside which the electronic power devices are placed.

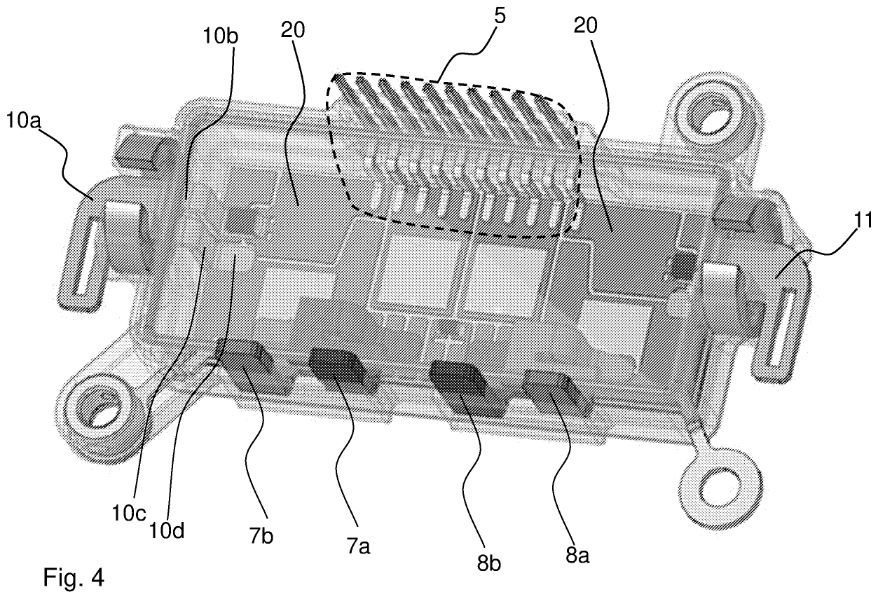

The support for the electronic power devices is for example:
a printed circuit board 20 on which a plurality of electronic power devices are mounted, as shown in FIG. 4;
a ceramic substrate with two levels of copper, known as “Direct Bonded Copper” (DBC).

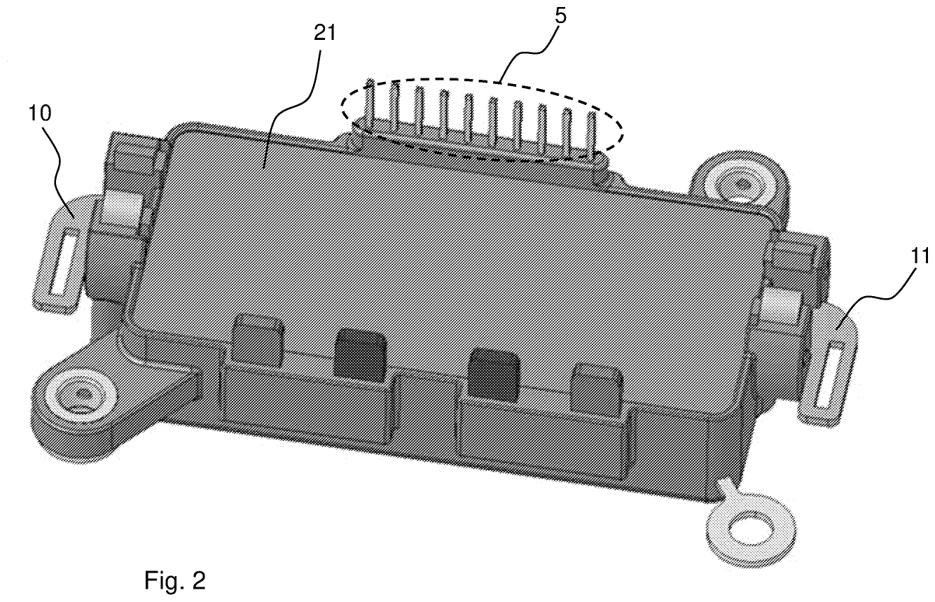

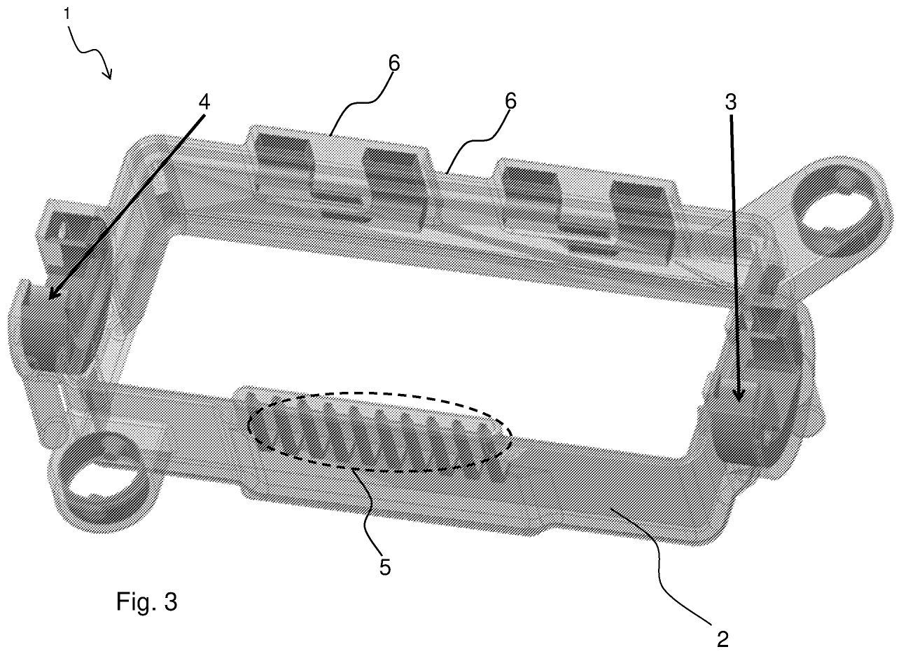

FIGS. 2 and 4 differ from FIGS. 1 and 3 in that the housing 1 is rotated by about 180 degrees.

More in particular, said electronic power devices implement an inverter having the function of converting a direct voltage generated by a rechargeable battery pack into an alternating voltage used to drive an electric machine operating as an electric motor.

The perimeter element 2 is made of electrically insulating material, in particular made of plastic material.

For the purposes of the present disclosure, the term “plastic material” (or “polymeric material”) means a wide range of synthetic or semi-synthetic polymeric organic compounds with high molecular weight that are malleable and can therefore be modelled into solid objects.

Said polymeric organic compounds can be pure (co)polymers or comprising other substances aimed at improving the properties and reducing costs, such as for example organic and/or inorganic additives.

For the purposes of the present disclosure, the term “(co)polymer” is used to indicate both the polymers, also known as homopolymers, i.e. macromolecules whose polymer chain contains repeating units obtained from the union of a single type of monomers, and copolymers, i.e. macromolecules whose polymer chain contains repeating units obtained by the union of two monomers of two or more varying types.

Preferably, the plastic material with which the perimeter element 2 is made is a thermoplastic polyphenylene sulphide polymer (PPS); in particular, the polymeric matrix has in its interior about a 50% percentage of fibre glass indicated with “Glass-filled polymer 50” (abbreviated GF50), i.e. PPS GF50.

The perimeter element 2 comprises walls having a thickness and a height (defined between the upper and lower edge of the respective wall) such to at least partially embed a pair of electrical metallic connectors 7a, 7b, a pair of electrical metallic connectors 8a, 8b, a pair of metal conductors 10, 11, a plurality of metal terminals 5; moreover, the perimeter element comprises respective portions such to embed a pair of concentrators 3, 4.

This is obtained by using a co-moulding of the perimeter element 2 with the electrical metallic connectors 7a, 7b, with the pair of electrical metallic connectors 8a, 8b, with the pair of metal conductors 10, 11, with the metal terminals 5 and with the pair of concentrators 3 and 4.

In other words, the pair of electrical metallic connectors 7a, 7b, the pair of electrical metallic connectors 8a, 8b, the pair of metal conductors 10, 11, the plurality of metal terminals 5 and the pair of concentrators 3 and 4 are at least partially embedded inside the respective portions of the perimeter element 2.

FIGS. 3 and 4 differ from FIGS. 1 and 2 in that the perimeter element 2 is transparent so as to show better the metal components that it embed at least partly.

The perimeter element 2 embeds a portion of the first pair of electrical metallic connectors 7a, 7b adapted to receive the positive and negative battery voltage generated by the battery pack, respectively.

Preferably, the perimeter element 2 embeds a further first pair of electrical metallic connectors 8a, 8b adapted to receive the positive and negative battery voltage generated by an additional battery pack, respectively.

The perimeter element 2 has for example a substantially rectangular shape.

The perimeter element 2 also embeds a portion of a pair of metal conductors 10, 11 (i.e. terminals) adapted to carry an alternating voltage for driving the electric machine when it operates as an electric motor.

The metal conductors 10, 11 are for example copper bars.

In particular, the pair of metal conductors 10, 11 is electrically connected to the stator windings of the electric machine.

The perimeter element 2 also embeds a portion of the plurality of metal terminals 5, which have the function of connecting the electronic power devices (mounted on the printed circuit board 20) with control logic circuits positioned outside the housing 1.

The perimeter element 2 also embeds a portion of a pair of concentrators 3 and 4 having the function of increasing the density of the magnetic flux of a respective magnetic field that crosses (at least partially) the pair of metal conductors 10, 11.

The perimeter element 2 has a height defined between its lower edge (for connection with the support for the electronic power devices) and its upper edge; the perimeter element 2 comprises a plurality of substantially flat, mutually adjacent walls, wherein:
a first wall embeds at least partially the metal conductor 10;
a second wall embeds at least partially the metal conductor 11;
a third wall embeds at least partially the pair of electrical metallic connectors 7a, 7b and the pair of electrical metallic connectors 8a, 8b;
a fourth wall embeds at least partially the plurality of metal terminals 5;

Preferably, the perimeter element 2 has a substantially rectangular shape and comprises substantially flat walls having a thickness and a height (defined as a direction perpendicular to the support plane) such to embed:
an intermediate portion of the pair of electrical metallic connectors 7a, 7b;
an intermediate portion of the pair of electrical metallic connectors 8a, 8b;
an intermediate portion of the pair of metal conductors 10, 11;
an intermediate portion of the plurality of metal terminals 5;
at least one portion of the pair of concentrators 3 and 4

For example, the thickness of the walls of the perimeter element 2 is comprised between 1 mm and 5 mm, while the height of the walls is comprised between 10 mm and 30 mm.

The magnetic flux concentrator 3 is adapted to generate a first magnetic field that at least partially crosses the metal conductor 10, while the magnetic flux concentrator 4 is adapted to generate a second magnetic field that at least partially crosses the metal conductor 11.

Therefore the metal conductor 10 comprises a portion crossing the magnetic flux concentrator 3 and similarly the metal conductor 11 comprises a portion crossing the magnetic flux concentrator 4, as it will be explained in more detail below.

The magnetic flux concentrator 3 comprises an air opening 3c adapted to house a first Hall sensor having the function of measuring the current flowing through the metal conductor 10, thus measuring the current flowing through the windings of the stator of the electric machine.

Similarly, the magnetic flux concentrator 4 comprises an air opening 4c adapted to house a second Hall sensor having the function of measuring the current flowing through the metal conductor 11, thus measuring the current flowing through the windings of the stator of the electric machine.

According to a preferred embodiment of the disclosure, the magnetic flux concentrator 3 is made of a ferromagnetic element having a partially toroidal shape surrounding the metal conductor 10 and which comprises a magnetic air gap 3c in which to place the first Hall sensor; in this case the housing 1 comprises a first seat in plastic material having a partially circular profile and adapted to house the toroidal ferromagnetic element 3 by snap-fitting the latter therein.

Advantageously, the ferromagnetic element 3 comprises a pair of wedge-shaped elements 3a, 3b arranged in the proximity of the magnetic air gap, which allow to further improve the density of the magnetic flux.

Similarly, the magnetic flux concentrator 4 is made of a ferromagnetic element having a partially toroidal shape surrounding the metal conductor 11 and which comprises a magnetic air gap 4c in which to place the second Hall sensor; in this case the housing 1 comprises a second seat made of plastic material having a partially circular profile and adapted to house the toroidal ferromagnetic element 4 by snap-fitting the latter therein.

Advantageously, the ferromagnetic element 4 comprises a pair of wedge-shaped elements 4a, 4b arranged in the proximity of the magnetic air gap, which allow further improving the density of the magnetic flux.

With reference to FIG. 4, it is possible to observe that the support for the electronic power devices is made of a printed circuit board 20 having a flat upper surface, on which the electronic power devices are mounted, such as for example high power switches (IGBT), transformers and capacitors.

The board 20 is made for example of a ceramic substrate with two levels of copper, known as “Direct Bonded Copper” (DBC).

The perimeter element 2 defines an opening having an upper edge in which a protection cover 21 is fixed and having a lower edge in which the printed circuit board 20 is fixed.

Advantageously, the metal conductor 10 comprises an intermediate portion which is embedded inside a portion of the perimeter element 2, it comprises an end portion outside the perimeter element 2 (i.e. it is not embedded therein) and comprises another end portion inside the perimeter element 2 and having an extension such to reach the lower edge of the opening of the perimeter element 2 so as to be in contact with the printed circuit board 20.

In particular, the metal conductor 10 is a metal bar (for example copper) co-moulded with the perimeter element 2 and the metal bar 10 extends through a wall of the perimeter element 2 adjacent to the concentrator 3, wherein the metal bar 10 comprises:
a portion 10a outside the perimeter element 2, in order to allow the engagement of an external electrical connector;
an intermediate portion 10b embedded into the wall crossing the same and integral with the wall;
another portion inside the perimeter element having an “L”-shaped profile composed of a first substantially rectilinear length 10c that extends between the embedded portion 10b and the lower edge of the wall and a second length 10d substantially transverse to the first length 10c and projecting inside the wall of the perimeter element 2, wherein the second length 10d defines an electrical connection to the printed circuit board 20.

The outer portion 10a has for example an “L” shape and comprises a portion that extends away from the wall adjacent to the concentrator 3 and another folded portion that extends along the wall itself.

Preferably, the first length 10c extends between the embedded portion 10b and the lower edge of the wall, along the height of the wall itself.

More generally, the inner portion of the metal bar 10 has the shape of an open, broken line composed of two sections.

The second length 10d of the metal bar 10 is fixed to the upper surface of the printed circuit board 20, for example by welding, press-fitting, connectors.

Since the metal bar 10 is co-moulded with the perimeter element 2 made of plastic material, the seal of the metal bar 10 in the perimeter element 2 is improved, i.e. the metal bar 10 cannot be released from the housing 1 during its use.

The above considerations concerning the form and co-moulding of the metal conductor 10 are applicable in a similar way to the metal conductor 11 as well, which is thus co-moulded with the perimeter element 2 and can be a metal bar (for example copper) extending to cross another wall of the perimeter element 2, wherein the metal bar 11 comprises an end portion outside the perimeter element 2, an intermediate portion embedded into another wall of the perimeter element 2 and another end portion inside the perimeter element having an “L”-shaped profile so as to electrically connect to the board 20.

Advantageously, the magnetic flux concentrator is co-moulded with the perimeter element 2 and the perimeter element 2 embeds the magnetic flux concentrator; in other words, the flux concentrator is fixed on a portion of the perimeter element and it is embedded inside the perimeter element 2.

The electrical connector 7a is co-moulded with the perimeter element 2 and the perimeter element 2 at least partially embeds the electrical connector 7a; in particular, the electrical connector 7a comprises a portion entirely embedded and integral with the inside of a portion of the perimeter element (for example, a wall) and comprises an end portion outside said portion (wall) of the perimeter element and projecting inside said perimeter element 2, said end portion defining an electrical connection with said support.

More in particular, the electrical connector 7a is composed of a first, substantially rectilinear metal portion partially embedded into the perimeter element 2 and of a second metal portion inside the perimeter element 2, wherein:
the first metal portion comprises a first length outside the perimeter element 2 and projecting from the upper edge of the wall of the perimeter element 2;
the first metal portion further comprises a second length embedded into the wall of the perimeter element 2 and integral with the wall, wherein the second length of the first portion extends between the upper and lower edge of the wall;
the second portion is inside the perimeter element 2 and comprises a substantially rectilinear length that defines an electrical connection to the board 20.

Since the metal bar 7a is co-moulded with the perimeter element 2 made of plastic material, the seal of the metal bar 7a in the perimeter element 2 is improved, i.e. the metal bar 7a cannot be released from the housing 1 during its use.

The above considerations concerning the shape and co-moulding of the electrical connector 7a are applicable in a similar way also to the connectors 7b, 8a, 8b, which thus can each one be composed of a first, substantially rectilinear metal portion partially embedded into the perimeter element 2 and of a second metal portion inside the perimeter element 2.

It should be noted that for the purposes of explanation of the disclosure, a perimeter element 2 has been shown in the figures having a substantially rectangular shape having walls which extend along its perimeter, but other forms of the perimeter element 2 can also be used, provided that this comprises suitable portions such to at least partially embed the pair of metal conductors 10, 11, the pair of electrical metallic connectors 7a, 7b, the pair of electrical metallic connectors 8a, 8b, the metal terminals 5 and the pair of concentrators 3 and 4. The housing 1 is used in an electric power supply system of the electric or hybrid vehicle provided with a three-phase asynchronous motor.

The electric power supply system comprises:
a rechargeable battery pack;
a three-phase electric motor;
three housings 1a, 1b, 1c (one for each phase of the motor), each implemented like the housing 1 previously illustrated;
three inverter electronic devices, each housed into a respective housing 1a, 1b, 1c;

three Hall sensors for respectively measuring the current of the three phases of the electric motor.

The rechargeable battery pack has the function of providing the electrical energy to drive the electric machine so as to operate like an electric motor, thus generating a battery voltage of the direct type.

Each of the three inverter electronic devices comprises a plurality of electronic power devices and each inverter electronic device is configured to receive battery voltage of the direct type and to generate therefrom the alternating voltage for driving a respective phase of the electric machine operating as an electric motor.

The electric motor comprises a rotor that is put in rotation and which in turn drives the movement of the wheels of the electric or hybrid vehicle.

More in particular, the first inverter electronic device is made by means of a first printed circuit board on which a plurality of electronic power devices are mounted, wherein:
said first board is housed in the first housing 1a;
the first inverter electronic device is electrically connected in input to the connectors 7a, 7b, 8a, 8b of the first housing 1a so as to receive the positive and negative battery voltage and is connected at its output with the metal conductors 10, 11 of the first housing 1a so as to carry a first alternating voltage for driving a first phase of the electric machine operating as an electric motor;
a first Hall sensor has a portion positioned in the opening of the first magnetic flux concentrator of the first housing 1a, in particular in the magnetic air gap of a first toroidal ferromagnetic element surrounding the metal conductor 10 of the first housing 1a;
a second Hall sensor has a portion positioned in the opening of the second magnetic flux concentrator of the first housing 1a, in particular in the magnetic air gap of a second toroidal ferromagnetic element surrounding the metal conductor 11 of the first housing 1a.

Similarly, the second inverter electronic device is made by means of a second printed circuit board on which a plurality of electronic power devices are mounted, wherein:
said second board is housed in the second housing 1b;
the second inverter electronic device is electrically connected in input to the connectors 7a, 7b, 8a, 8b of the second housing 1b so as to receive the positive and negative battery voltage and is connected at its output with the metal conductors 10, 11 of the second housing 1b so as to carry a second alternating voltage for driving a second phase of the electric machine which operates as an electric motor;
a third Hall sensor has a portion positioned in the opening of the first magnetic flux concentrator of the second housing 1b, in particular in the magnetic air gap of a first toroidal ferromagnetic element surrounding the metal conductor 10 of the second housing 1b;
a fourth Hall sensor has a portion positioned in the opening of the second magnetic flux concentrator of the second housing 1b, in particular in the magnetic air gap of a second toroidal ferromagnetic element surrounding the metal conductor 11 of the second housing 1b.

Finally, the third inverter electronic device is made by means of a third printed circuit board on which a plurality of electronic power devices are mounted, wherein:
said third board is housed in the third housing 1c;
the third inverter electronic device is electrically connected in input to the connectors 7a, 7b, 8a, 8b of the third housing 1c so as to receive the positive and negative battery voltage and is connected at its output with the metal conductors 10, 11 of the third housing 1c so as to carry a third alternating voltage for driving a third phase of the electric machine which operates as an electric motor;
a fifth Hall sensor has a portion positioned in the opening of the first magnetic flux concentrator of the third housing 1c, in particular in the magnetic air gap of a first toroidal ferromagnetic element surrounding the metal conductor 10 of the third housing 1c,
a sixth Hall sensor has a portion positioned in the opening of the second magnetic flux concentrator of the third housing 1c, in particular in the magnetic air gap of a second toroidal ferromagnetic element surrounding the metal conductor 11 of the third housing 1c.

1. Housing for electronic power devices for driving an electric motor of an electric or hybrid vehicle, the housing comprising a perimeter element in plastic material adapted to house a support for electronic power devices,
the perimeter element comprising:
an electrical connector adapted to receive a direct voltage generated by a battery pack;
a metal conductor adapted to carry an alternating voltage to drive the electric motor;
a magnetic flux concentrator adapted to generate a magnetic field at least partially crossing the metal conductor;
wherein said concentrator surrounds the metal conductor and comprises an air opening adapted to house a Hall sensor to measure the current flowing across the metal conductor;
wherein the perimeter element and the metal conductor are co-moulded and said perimeter element at least partially embeds the metal conductor by means of a co-moulding of said metal conductor with the perimeter element made of plastic material.

2. Housing according to claim 1, wherein the metal conductor comprises a portion entirely embedded and integral with the inside of a portion of the perimeter element and comprises an end portion outside of said portion of the perimeter element, so as to allow the fixing of the end portion of the metal conductor to the support.

3. Housing according to claim 2, wherein the perimeter element has a height defined between its lower edge, for connection with said support, and its upper edge and comprises a plurality of substantially flat, mutually adjoining walls, wherein at least one of said substantially flat walls has a thickness and a height that at least partially embeds said metal conductor,
and wherein said metal conductor is a metal bar extending through said at least one wall and comprising:
a portion outside said perimeter element;
a portion embedded into the wall, crossing the same;
a portion inside said perimeter element having an open, broken-line profile formed by:
a first substantially rectilinear length extending between the embedded portion and the lower edge;
second length transverse to the first length and projecting inside said perimeter element and defining an electrical connection with said support.

4. Housing according to claim 1, wherein the perimeter element and the magnetic flux concentrator are co-moulded and the perimeter element comprises a portion embedding the magnetic flux concentrator.

5. Housing according to claim 1, wherein the perimeter element and the electrical connector are co-moulded and the perimeter element at least partially embeds the electrical connector, the electrical connector comprising a portion entirely embedded and integral with the inside of a portion of the perimeter element and comprises an end portion outside said portion of the perimeter element and projecting inside said perimeter element, said end portion defining an electrical connection with said support.

6. Housing according to claim 5, wherein the electrical connector comprises a substantially rectilinear metal portion partially embedded into the perimeter element and comprises a second metal portion inside the perimeter element, wherein:
the first metal portion comprises a first length outside the perimeter element and projecting from the upper edge of the wall of the perimeter element;
the first metal portion further comprises a second length embedded into the wall of the perimeter element 2 and integral with the wall, wherein the second length of the first portion extends between the upper and lower edge of the wall;
the second portion is inside the perimeter element and comprises a substantially rectilinear length defining an electrical connection to the support

7. Housing for electronic power devices according to claim 1, wherein the concentrator is a ferromagnetic element having a partially toroidal shape surrounding the metal conductor, wherein said air opening is a magnetic air gap adapted to house the Hall sensor.

8. Housing for electronic power devices according to claim 7, wherein the ferromagnetic element comprises a pair of wedge-shaped elements arranged in the proximity of the magnetic air gap.

9. Housing for electronic power devices according to claim 1, wherein the perimeter element comprises:
a pair of electrical connectors to receive the direct voltage generated by a battery pack;
a pair of metal conductors adapted to carry the alternating voltage to drive the windings of the electric motor;
a pair of elements made of ferromagnetic material, each element being adapted to generate a respective magnetic field at least partially crossing the respective metal conductor;
wherein each ferromagnetic element has a respective partially toroidal shape surrounding the respective metal conductor and comprises a respective opening adapted to house a respective Hall sensor to measure the current flowing across the respective metal conductor.

10. Housing for electronic power devices according to claim 1, comprising at least one seat made of plastic material having a partially circular profile and being adapted to house a respective toroidal ferromagnetic element by snap-fitting the latter therein.

11. System for supplying electric power to an electric or hybrid vehicle, the system comprising:
a battery pack configured to supply a direct battery voltage;
an inverter electronic device comprising the electronic power devices,
wherein the inverter electronic device is configured to receive the battery voltage and to generate therefrom the alternating voltage;
an electric motor connected with the output of the inverter electronic device;
a housing according to any one of the preceding claims;
a Hall sensor having a portion that is housed in the opening of the magnetic flux concentrator;
wherein the inverter electronic device is electrically connected at the input with the first electrical connector adapted to receive the battery voltage and is electrically connected at the output with the metal conductor adapted to carry the alternating voltage.

12. Electric power supply system according to claim 11, comprising three housings according to claim 1, a three-phase asynchronous electric motor and three Hall sensors adapted to measure a respective phase current, wherein each housing is adapted to house a respective board or substrate on which a respective inverter electronic device is mounted, each housing comprising a respective metal conductor adapted to carry a respective alternating voltage to control a respective phase of the electric motor.

13. Electric power supply system according to claim 5, wherein each one of the three Hall sensors comprises a respective portion arranged in the magnetic air gap of the respective toroidal element.

14. Housing according to claim 2, wherein the perimeter element and the magnetic flux concentrator are co-moulded and the perimeter element comprises a portion embedding the magnetic flux concentrator.

15. Housing according to claim 3, wherein the perimeter element and the magnetic flux concentrator are co-moulded and the perimeter element comprises a portion embedding the magnetic flux concentrator.

16. Housing according to claim 2, wherein the perimeter element and the electrical connector are co-moulded and the perimeter element at least partially embeds the electrical connector,
the electrical connector comprising a portion entirely embedded and integral with the inside of a portion of the perimeter element and comprises an end portion outside said portion of the perimeter element and projecting inside said perimeter element, said end portion defining an electrical connection with said support.

17. Housing according to claim 3, wherein the perimeter element and the electrical connector are co-moulded and the perimeter element at least partially embeds the electrical connector,
the electrical connector comprising a portion entirely embedded and integral with the inside of a portion of the perimeter element and comprises an end portion outside said portion of the perimeter element and projecting inside said perimeter element, said end portion defining an electrical connection with said support.

18. Housing according to claim 16, wherein the electrical connector comprises a substantially rectilinear metal portion partially embedded into the perimeter element and comprises a second metal portion inside the perimeter element, wherein:
the first metal portion comprises a first length outside the perimeter element and projecting from the upper edge of the wall of the perimeter element;
the first metal portion further comprises a second length embedded into the wall of the perimeter element 2 and integral with the wall, wherein the second length of the first portion extends between the upper and lower edge of the wall;
the second portion is inside the perimeter element and comprises a substantially rectilinear length defining an electrical connection to the support.

19. Housing according to claim 17, wherein the electrical connector comprises a substantially rectilinear metal portion partially embedded into the perimeter element and comprises a second metal portion inside the perimeter element, wherein:
the first metal portion comprises a first length outside the perimeter element and projecting from the upper edge of the wall of the perimeter element;
the first metal portion further comprises a second length embedded into the wall of the perimeter element 2 and integral with the wall, wherein the second length of the first portion extends between the upper and lower edge of the wall;
the second portion is inside the perimeter element and comprises a substantially rectilinear length defining an electrical connection to the support.
